(19) United States
(12) Patent Application Publication
(10) Pub. No.: US 2008/0087315 A1
(43) Pub. Date: Apr. 17, 2008

(54) Thermoelectric Fan for Radiation-Based Heaters, and Methods Related Thereto

(75) Inventors: Glenn I. Deming, Lunenburg, MA (US); Timothy R. Membrino, Acton, MA (US); Roger Wood, Winchendon, MA (US); Douglas S. Olsen, Natick, MA (US); Kang P. Lee, Sudbury, MA (US); S. Ronald Wysk, Stow, MA (US)

Correspondence Address: LUCY ELANDJIAN;IP LAW SERVICES, LLC., P O BOX 4557, EDWARDS, CO, 81632, US

(73) Assignee: ASPEN SYSTEMS, INC., Marlborough, MA (US)

(21) Appl. No.: 11/871,926

(22) Filed: Oct. 12, 2007

Related U.S. Application Data
(60) Provisional application No. 60/829,372, filed on Oct. 13, 2006.

(51) Int. Cl. H01L 35/28; B23P 15/26; F01D 5/18; F25B 21/02

(52) U.S. Cl. 136/203; 29/888.025; 415/177; 62/3.2

(57) ABSTRACT

Disclosed is a thermoelectric fan for use with radiant heaters, particularly catalytic heaters. The thermoelectric fan of the present invention comprises a housing sub-assembly coupled to a thermal plate sub-assembly, the housing sub-assembly comprising a shrouded circulating air moving member, such as a fan blade, powered solely by the conversion of heat from a separate heater into electricity via an integrated thermoelectric module. Also disclosed is a self-powered fan that can safely perform in hazardous atmospheres while converting radiant heat to circulate air. The thermoelectric fan of the present invention ensures that the air within the space to be heated is more effectively distributed and temperature gradients are minimized. Also disclosed are methods for assembling, installing and safe operation of the thermoelectric fan.

### CROSS REFERENCE TO RELATED APPLICATION

This is a non-provisional application claiming the benefit of and priority to provisional patent application having serial number 60/829,372 and filed on Oct. 13, 2006, which is incorporated herein by reference.

### TECHNICAL FIELD

The present invention relates generally to a thermoelectric fan for use with radiant heaters, and methods related thereto. Specifically, the present invention pertains to a shrouded circulating air moving member, powered solely by the conversion of heat from a separate catalytic heater into electricity via an integrated thermoelectric module. The present invention also pertains to a self-powered fan that can safely perform in hazardous atmospheres while converting radiant heat to circulate air.

### BACKGROUND

The advent of commercially available thermoelectric devices has allowed for unique application of this technology to the solution of various thermal management and low power generation problems. For example, Aspen Systems, Inc. has successfully applied thermoelectric modules for generating electricity in small portable fans for military applications.

In industrial applications, space heaters are often used to prevent damage to critical equipment exposed to cold ambient temperatures. Many of these applications have no electrical power source available to them. Without an electrical power source, the use of fans or blowers to help efficiently distribute the air within the heated space is difficult. In these cases, a thermoelectric module may be coupled to the heater and used to generate the required electrical energy to power a fan or blower. As an example, the petroleum processing industry is faced with the problem of maintaining operation of oil drilling and processing equipment at unmanned, remote sites. The equipment is typically enclosed in a simple shelter with no available source of electricity. To prevent freeze-up and malfunction of the equipment, the shelter is heated using a liquid-propane or natural gas radiant heater. The environment is often further complicated by the presence of flammable or even explosive mixtures of gases. While the radiant heater provides some level of freeze protection, the efficiency of heating the enclosed space is low while the temperature gradients between the floors, corners and ceiling are high. Thus, critical equipment remain at risk of freezing and damage as a result of isolated low temperatures within the enclosure.

Various liquid-propane and natural gas radiant heaters, such as the Cata-Dyne heaters (from CCI Thermal Technologies, Inc., Edmonton, Alberta, Canada), infrared radiant heaters (from Bruest Catalytic Heaters, a division of Catalytic Industrial Group, Inc., Independence, Kans.), and catalytic heaters (from the Catalytic Heater Company, Terrell, Tex.), exist. However, these heaters do not include a fan or blower to distribute air within the heated space.

Examples of commercially available thermoelectrically powered fans include a thermoelectric fan TEF (manufactured by Aspen Systems, Inc., Marlborough, Mass.), which is designed to function with military space heaters, the Space Heater Convective (manufactured by Hunter Manufacturing Company, Solon, Ohio), a heater with an integrated fan powered by a thermoelectric module, and the Ecofan™ (manufactured by Caframo Ltd., Wiarton, Ontario, Canada), which is designed to circulate air when placed on wood stoves. Each of these fans generates its own power via conductive heat transfer.

The existing thermoelectric fans are typically designed for operation using conductive heat transfer from a heated surface on the heater into the thermoelectric module. These thermoelectric fans are not capable of efficient operation with heaters using radiant heat transfer as the primary means of transferring heat from the heated surface into the thermoelectric module. Existing thermoelectric fans are not designed to operate efficiently with a catalytic heater which requires a continual flow of fresh Oxygen into the catalyst bed, which is part of the heated surface, to maintain heater performance and efficiency. Applying existing thermoelectric fans to a catalytic heater would not yield the desired results because these fans require direct contact between the heated surface and a heat transfer member thermally connected to the thermoelectric module. The attachment of the heat transfer means to the heated surface of the catalytic heater will block the flow of fresh Oxygen into the catalyst, resulting in shutting down of the catalytic process and a drop in heater temperature and efficiency. The design or modification of existing thermoelectric fans for use with this type of heater represents a significant technical challenge as the optimal spacing between the fan and the heater must be determined and maintained to ensure sufficient flow of fresh Oxygen into the catalyst to maintain the catalytic process and thus heater temperature and efficiency. Additionally, as the heat transfer means should not be physically contacting the heated surface of the heater, the design of the heat transfer means for transferring heat from the heated surface via radiation to the thermoelectric module must be determined to ensure efficient performance of both the fan and the heater.

Some currently available thermoelectric fans utilize a secondary cold airflow stream, independent from the primary airflow stream which is pulled across the hot surface of the heater. The bulk of the secondary cold airflow stream is directed across a heat exchanger surface in thermal communication with the cold side of the thermoelectric module and thus provides the thermal heat sink required to maintain a heat transfer gradient across the thermoelectric module. A portion of the secondary cold airflow stream is directed across the hot heat exchanger in thermal communication with the heated surface of the heater. Said airflow portion strips heat from the hot heat exchanger to prevent damage to the thermoelectric module from an overheated condition. With this approach, only a portion of the total fan airflow is pulled across the heated surface and heated prior to being distributed into the room, thereby reducing the efficiency of the fan for distributing hot air into the room. Other thermoelectric fans utilize a single airflow stream, which is pulled across the cold heat exchanger and then blown onto the heated surface of the heater. While more efficient for airflow distribution, this approach will not work with a catalytic heater, where the forced airflow blowing onto the heated surface will degrade the catalytic process and reduce the heater surface temperature, thus degrading the fan performance. In addition, directing airflow onto the heated surface will disturb the transfer of radiant heat from the heated surface to the thermoelectric module. The heat transfer means that transfers heat from the heated surface to the thermoelectric module would be cooled by the directed airflow blowing onto the surface, negating the required thermal gradient between the heat transfer means and the thermoelectric module.

Some currently available thermoelectric fans utilize a feature on the heat transfer means to reduce the contact between said means and the heated surface of the heater. Such fans reduce said contact to reduce the heat transfer to the thermoelectric module so as to prevent a potential over-temperature condition with an excessively hot heater surface, which could damage the thermoelectric module. The means of reducing contact between the heat transfer means and the hot surface of the heater requires the angling of the heat transfer means away form the heated surface of the heater at one end while the heat transfer means maintains a line to surface contact with the heated surface of the heater at the opposite end. As a result, the heat transfer means is angled relative to the heated surface of the heater but still in physical contact along the pivot edge. This approach will not suffice with a catalytic heater which requires flow of fresh Oxygen into the catalyst bed, which is part of the heated surface, to maintain heater performance and efficiency. Said flow of fresh air will be blocked and constricted by the angled heat transfer means in the existing fan.

Existing thermoelectric fans are also incapable of safe operation in hazardous atmospheres that contain explosive and/or flammable gases. The thermoelectric module has the potential to generate sufficient electrical energy and transfer that energy into the motor. The motor coil may be of sufficient inductance that the potential stored energy is significant and can result in ignition or explosion of surrounding gases. Existing thermoelectric fans do not have any means of preventing an ignition or explosion in such an event.

### SUMMARY OF THE INVENTION

Various thermoelectric fans exist; however, these thermoelectric fans are not designed for efficient operation with catalytic type radiant heat sources. Further, the existing thermoelectric fans are not capable of safe operation in hazardous atmospheres.

In view of the above, there is a need for a thermoelectric fan for use with catalytic heaters to improve the distribution of heat within the heated space.

It is, therefore, an aspect of the present invention to provide a thermoelectric fan for use with radiant-based heaters, specifically, catalytic type radiant heaters.

It is another aspect of the present invention to provide a thermoelectric fan for improving the distribution of the heat within the heated space.

It is another aspect of the present invention to provide a thermoelectric fan that can safely perform in hazardous atmospheres.

The present invention pertains to a shrouded fan that uses an integrated thermoelectric module for power. The fan assembly, comprising a housing sub-assembly and a thermal plate sub-assembly, is mounted on a heated surface of a radiant heater, particularly catalytic type radiant heater, such that the thermoelectric module is within the heat path. A D.C. voltage is generated when heat is transferred through the thermoelectric module. The resulting electricity is used to power a D.C. motor that turns at least one air moving member, such as a fan blade. The generated D.C. current is attenuated to control the energy level and to prevent spark formation, as the current could otherwise be an ignition source. Due to the rotation of the air moving member, ambient air is pulled into the fan housing through the inlet and exhausted through the outlet of the fan housing. The thermoelectric fan therefore distributes the heated air within the heated space where the fan is installed. The result is a more uniform temperature distribution, reduction of cold/hot spots, and increase in efficiency for heating the space. These benefits are achieved at least in part due to a space between the thermoelectric fan and the heater, said space being facilitated by an extension member. The fan of the present invention is useful with various types of radiant heat sources, particularly, with catalytic heaters, and within a hazardous atmosphere.

The above summary of the present invention is not intended to describe each illustrated embodiment or every implementation of the present invention. The figures and the detailed description that follow particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 illustrates a cross-sectional view of the thermoelectric fan (without the heater being visible) and the airflow stream therethrough, according to an embodiment of the present invention;

FIG. 2 illustrates a cross-sectional view of the thermoelectric fan's housing sub-assembly, according to an embodiment of the present invention;

FIG. 3 illustrates a cross-sectional view of the thermoelectric fan's thermal plate sub-assembly, according to an embodiment of the present invention;

FIG. 4 illustrates a top view of the housing sub-assembly showing the intrinsic safety circuit board assembly mounted therein (fan blade not shown), according to an embodiment of the present invention;

FIG. 5 illustrates the electrical schematic for the intrinsic safety circuit board assembly, according to an embodiment of the present invention; and

FIG. 6 illustrates the electrical wiring interconnections within the thermoelectric fan, according to an embodiment of the present invention.

### DETAILED DESCRIPTION

The present invention pertains to a thermoelectric fan, specifically, a shrouded circulating air moving member, such as a fan blade, powered solely by the conversion of heat from a separate heater into electricity via an integrated thermoelectric module. The present invention also pertains to a self-powered fan that can safely perform in hazardous atmospheres. The thermoelectric fan of the present invention enables the air within a given space to be more effectively distributed and ensures that the temperature gradients are minimized. The thermoelectric fan is suitable for use with various types of radiation-based heaters, particularly catalytic heaters.

### 1. Definitions

The term “hazardous atmospheres”, as used herein, refers to atmospheres containing concentrations of explosive and/or flammable gases.

It is to be understood that the singular forms of “a”, “an”, and “the”, as used herein and in the appended claims, include plural reference unless the context clearly dictates otherwise.

### 2. Thermoelectric Fan

The thermoelectric fan of the present invention is configured and designed for improved efficiency and greater safety. Whereas thermoelectric fans in the prior art are designed to operate based on conductive heat transfer through direct physical contact with a heated surface on the heater, the thermoelectric fan of the present invention is designed for efficient operation with radiant-based heaters, particularly, catalytic heaters. The present invention comprises features useful for securing the fan to a radiant-based heater. In a preferred embodiment, the thermoelectric fan is used with a catalytic type radiant heater. The present invention comprises the features to efficiently transfer radiant heat from the catalytic heater into a component of the fan while maintaining high heater efficiency. The present invention also comprises energy limiting components that eliminate the potential for an ignition or an explosion when operating in a hazardous atmosphere. The thermoelectric fan of the present invention involves the movement of a single airflow stream across a heat exchanger surface and then across the heated surface of the heater.

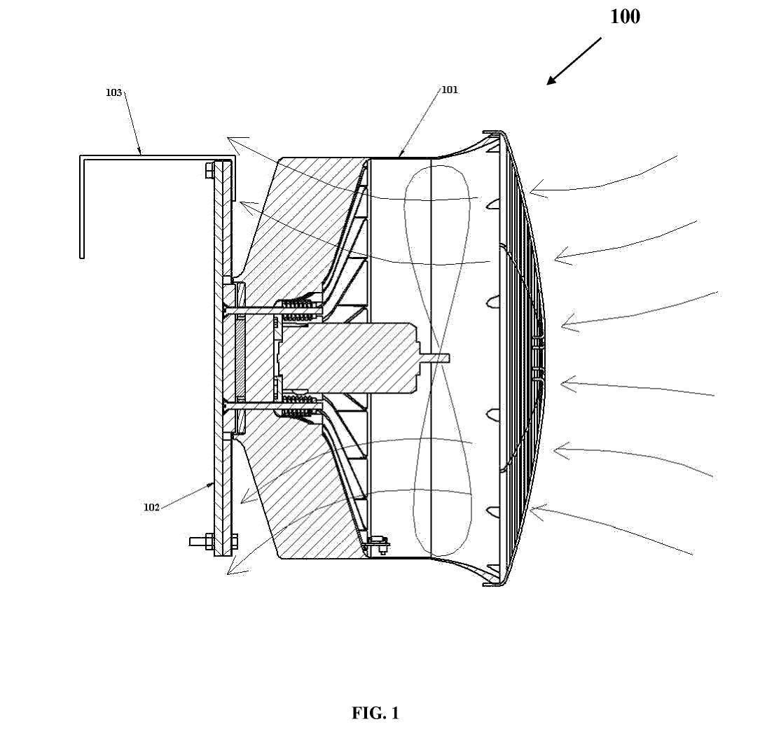

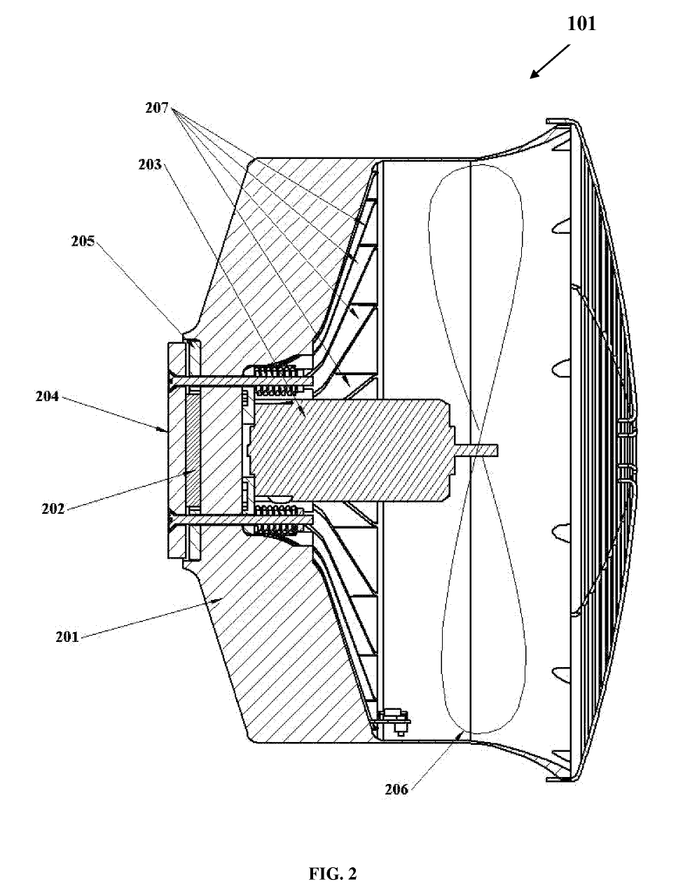

The thermoelectric fan 100 of the present invention, as illustrated in FIG. 1, comprises two primary sub-assemblies: 1) a housing sub-assembly 101, and 2) a thermal plate sub-assembly 102. In one embodiment shown in FIG. 1 and FIG. 2, the housing sub-assembly 101 comprises a fan housing 201, preferably circular but may be of any suitable geometric configuration. The housing 201 comprises at least one heat transfer member to serve as a heat exchanger and to transfer heat from the cold side of a thermoelectric module 202. In one embodiment, the at least one heat transfer member is at least one integrated thermal fin 207. The housing 201 may also comprise a protective covering or a grill. A D.C. brush motor (“motor”) 203, coupled to the fan housing 201, is preferably mounted in the center of the fan housing cavity. The motor 203 is also coupled to at least one air moving member. In one embodiment, the at least one air moving member is at least one fan blade 206. The motor 203 rotates the at least one fan blade 206. The specification of the motor 203 suitable for use herein is based on the power output from the thermoelectric module 202, the inertia and desired speed of the air moving member, and the winding and inertial characteristics of the motor 203. A heat exchanger disk 204 is in contact with the thermoelectric module 202 to provide a direct heat path from the heat exchanger disk 204 to the thermoelectric module 202, and to serve as a means for retaining the thermoelectric module 202 between the heat exchanger disk 204 and an outer surface of the fan housing 201. In one embodiment, heat exchanger disk 204 retains the thermoelectric module 202 to the outer surface of the housing 201 via a fastening means. At least one insulating pad 205 surrounds the outer perimeter of the thermoelectric module 202 to prevent or minimize contact between the heat exchanger disk 204 and the fan housing 201. In this embodiment, the thermoelectric module 202 is isolated within an efficient heat transfer path. The hot side of the thermoelectric module 202 is located against the heat exchanger disk 204, and the cold side of the thermoelectric module 202 is located against the fan housing 201, which serves as a cold side heat exchanger between the thermoelectric module 202 and the airflow stream. The heat exchanger disk 204 is in thermal communication with a heater. Heat is transferred from the heater into the heat exchanger disk 204, then through the thermoelectric module 202, and out to the fan housing 201. When heat is transferred through the thermoelectric module 202, it is converted to a D.C. voltage, which is used to power the motor 203. When powered, the motor 203 propels the at least one moving member. In one embodiment, the motor 203 spins the at least one fan blade 206, whereby the ambient air is pulled into the fan housing 201 and directed past the at least one heat transfer member. This airflow is then directed out of the fan housing outlet, across the heater surface and into the heated space. The airflow across the at least one heat transfer member provides a forced convection effect to transfer heat from the thermoelectric module 202, into the fan housing 201, and out to the airflow.

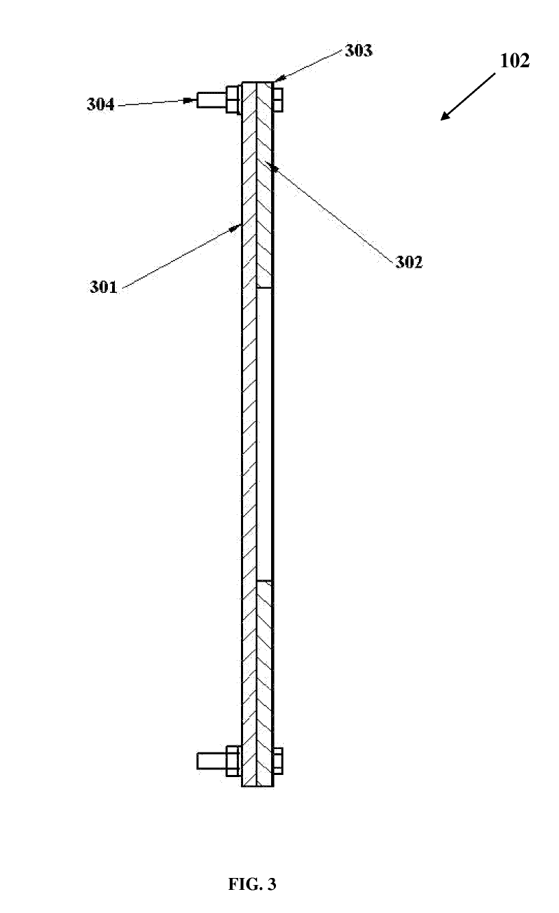

The thermal plate sub-assembly 102, shown in detail in FIG. 3, provides the means for adapting the housing sub-assembly 101 for use with radiant heaters, preferably catalytic heaters. The thermal plate sub-assembly 102 comprises a thermal plate 301. The thermal plate 301 may comprise any shape in conformity with the geometry of the heated surface, including but not limited to, a rectangle, a square, and a circle. The thermal plate 301 is preferably sized to match the shape and size of the given heater. The size and shape of the thermal plate 301 is determined to ensure that the frontal area of the thermal plate 301 blocks the airstream exiting from the housing sub-assembly 102. The blocking prevents the airstream from blowing directly onto and cooling the heater surface. In addition to blocking the airstream, the thermal plate 301 redirects the airstream to blow across the heated air in front of the heated surface and thereby promotes distribution of heated air within the environment. The thermal plate 301 is designed for no physical contact with the heater. The thermal plate 301 preferably comprises a thermally conductive metallic material, and typically, its thickness is in the range of from about 0.0625 inches (in.) to about 1.0 in. In another embodiment, the thermal plate 301 is fabricated from a thermally conductive non-metallic material. In another embodiment, the thermal plate 301 is sprayed with a thermally conductive material. In another embodiment, the thermal plate 301 is coated or plated with a thermally conductive material. The thermal plate 301 captures heat from the heater surface via radiation, and conductively transfers that heat into the heat exchanger disk 204. The heated surface of the thermal plate 301 is preferably black or dark in color to improve radiant heat transfer from the heater to the thermal plate 301.

The thermal plate 301 is insulated on the side opposite the heater with an insulation sheet 302 comprising a shape and size consistent with that of the thermal plate 301. The insulation sheet 302 prevents the airstream exiting from the housing sub-assembly 102 from cooling the thermal plate 301. If the airstream directly impacts the thermal plate 301, then the thermal plate 301 temperature is reduced due to the heat transfer from the thermal plate 301 to the airstream. The reduction of thermal plate 301 temperature results in a loss of the required thermal gradient between the thermal plate 301 and the thermoelectric module 202, and a resulting loss in performance of the thermoelectric fan 100. The insulation sheet 302 has a thickness in the range of from about 0.0625 in. to about 1.0 in. In a preferred embodiment of the present invention, the insulation sheet 302 comprises a hole in the center to facilitate the attachment of and thermal communication between the thermal plate 301 and the heat exchanger disk 204. In an alternate embodiment, the insulation sheet 302 comprises a thermally conductive section, rather than a hole, to facilitate the thermal communication between the thermal plate 301 and heat exchanger disk 204. The insulation sheet 302 improves the efficiency of the thermoelectric fan of the present invention by minimizing loss of heat due to the cooling effect of the airflow as it exits the fan housing 201 and blows against the thermal plate 301. In a preferred embodiment, the insulation sheet 302 is secured against the thermal plate 301 and protected from damage via an insulation shield 303. The insulation shield 303 can comprise any suitable rigid or stiff material, such as a metallic material or a plastic material. In a preferred embodiment, the insulation shield 303 is thin and comprises a metallic material. The insulation shield 303 has a thickness in the range of from about 0.01 in. to about 0.125 in. In a preferred embodiment, the insulation shield 303 comprises a hole in the center to facilitate the attachment of the thermal plate 301 to the heat exchanger disk 204. The insulation shield 303 holds the insulation sheet 302 firmly against the thermal plate 301, thus improving the insulation effectiveness and providing protection to the insulation sheet 302 when the thermoelectric fan 100 is handled and is in operation. In one embodiment of the present invention, the insulation sheet 302 is attached to the thermal plate 301 via an adhesive, and in another embodiment, the insulation sheet 302 is a sprayed-on insulation resulting in the insulation sheet 302 and the thermal plate 301 forming one component rather than the insulation sheet 302 being separate and distinct from the thermal plate 301; the configuration of these two embodiments obviates the need for an insulation shield 303.

The thermal plate sub-assembly 102 is assembled with at least one fastening means 304. The fastening means includes, but is not limited to, a bolt, a clip, an adhesive, and a weld. The thermal plate sub-assembly 102 may be fastened in any appropriate location, preferably in the corners of thermal plate 301 and the insulation shield 303. In a preferred embodiment, the at least one fastening means 304 also serves the function of an extension member to ensure that the proper spacing is maintained between the heated surface of the thermal plate 301 and the heater surface upon installation. In another embodiment, the thermal plate sub-assembly 102 comprises an extension member and at least one fastening means 304 which are separate and distinct from each other. In alternate embodiments, extension member may be integrated into an element of the housing sub-assembly or into an element of the thermal plate sub-assembly, for example, the extension member may be integrated with the thermal plate 301, or the fastening means 304, or the fan housing 201. The spacing between the heater surface and the thermal plate 301 is in the range from about 0.125 in. to about 1.0 in. The extension member is constructed of certain length to facilitate said spacing, as the spacing is critical to the efficient functioning of the thermoelectric fan 100 with catalytic heaters. Catalytic heaters require sufficient airflow to maintain efficient operation. If the thermal plate 301 is spaced too close to the heated surface, the airflow is significantly reduced and the heater surface temperature drops, resulting in poor performance of the thermoelectric fan 100. If the thermal plate 301 is spaced too far from the heated surface, the radiant heat transfer mechanism is reduced, thus the heat transferred to the thermoelectric module 202 and the corresponding electricity generated are reduced, resulting in poor performance of the thermoelectric fan 100. The spacing is important to ensure that there is no physical contact between the thermal plate 301 and the heated surface of the heater upon installation. The stated spacing range for the invention has been determined through great experimentation so as to provide optimal heat transfer between the thermoelectric fan 100 and the catalytic heater. The particular spacing for use herein, within the stated spacing range, is determined in combination with the specific type of a catalytic heater, the thermal plate 301 material, the thermal plate 301 color, the insulation sheet 302 material, the thermoelectric module 202 temperature and power specifications, the motor 203 inertia and power specifications, the air moving member shape and inertia, and the housing 201 shape, design and thermal performance to yield optimal heat transfer. As these components are coupled together, they consequently impact the proper selection of spacing to ensure optimal heater surface temperature, heater performance and thermoelectric fan 100 performance.

In one embodiment of the present invention, the thermal plate sub-assembly 102 is in thermal communication with the heat exchanger disk 204 of the housing sub-assembly 101. In a preferred embodiment, as illustrated in FIG. 1 and FIG. 2, the thermal plate sub-assembly 102 of the thermoelectric fan 100 is secured to heat exchanger disk 204 of the housing sub-assembly 101. At least one securing means, such as a mounting bracket, 103 is preferably used to secure the thermoelectric fan 100 to a heater while the thermoelectric fan 100 is in operation.

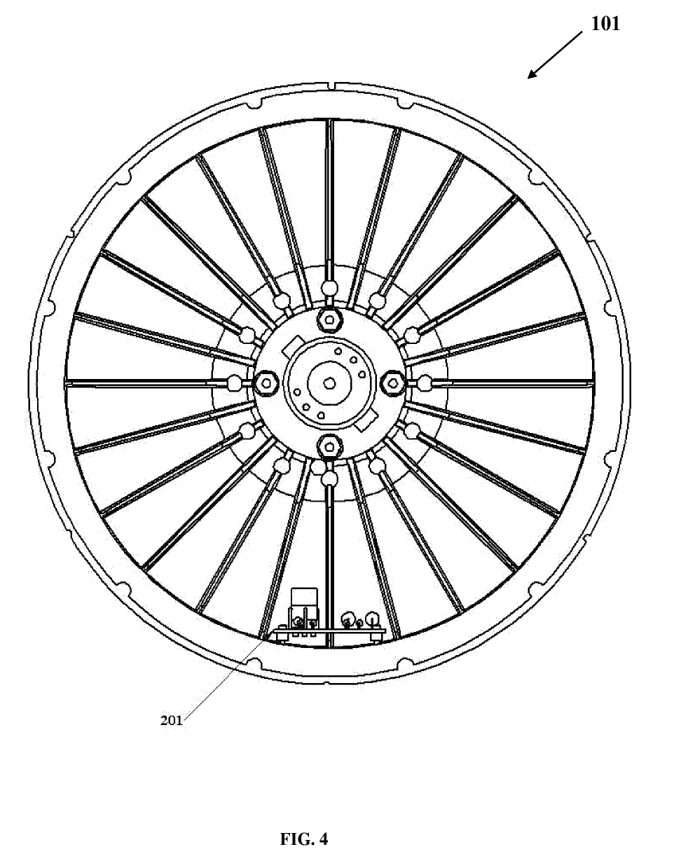

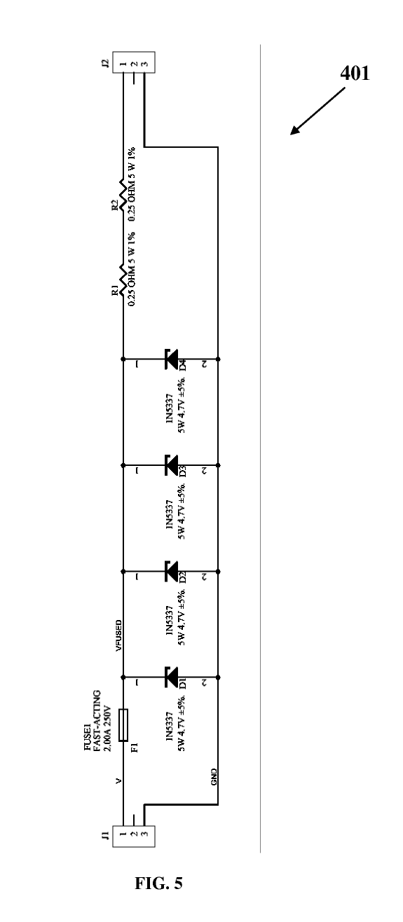

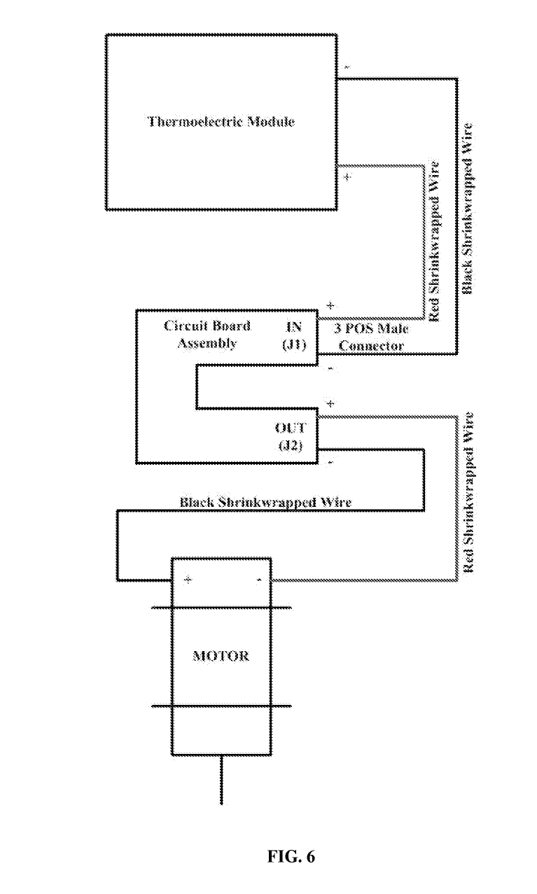

In one embodiment of the present invention, a circuit board assembly 401 is mounted to the inside wall of the fan housing 201. In another embodiment, as shown in FIG. 4, a circuit board assembly 401 is mounted against the inside wall of the fan housing 201 in at least one space created between at least two thermal fins 207. In alternate embodiments, the circuit board assembly 401 is mounted in other locations in the thermoelectric fan 100. In another embodiment, the thermoelectric module 202 is located on the circuit board assembly 401 and the circuit board assembly 401 is positioned in thermal communication between the heat exchanger disk 204 and the fan housing 201. The circuit board assembly 401 is necessary for safe operation of the thermoelectric fan 100 within hazardous atmospheres; however, non-hazardous atmospheres may not require the incorporation of the circuit board assembly 401 in the thermoelectric fan 100. The circuit board assembly 401 comprises one to four Zener diodes, one to four resistors, and at least one fuse to limit the voltage and current from the thermoelectric module 202 to the motor 203. The suitable specification for the Zener diodes is in the range of from about 1 Volt D.C. to about 10 Volt D.C. The suitable specification for the resistors is in the range of from about 0.1 Ohm to about 10 Ohm. The suitable specification for the fuse is in the range of about 0.5 amperes (Amps) to about 10 amperes. Due to this design configuration, the circuit board assembly 401 limits the energy within the electrical circuit to safe levels, which have been determined through CSA Intrinsic Safety qualification testing and approval, in order to prevent generation of a spark that could cause ignition of the explosive atmosphere. The design of the circuit board assembly 401 is shown in FIG. 5. The wiring connectivity between the thermoelectric module 202 the circuit board assembly 401 and the motor 203 is illustrated in FIG. 6. All power from the thermoelectric module 202 is routed through the circuit board assembly 401 and thus limited before reaching the motor 203, as required for safe operation of the thermoelectric fan 100 in explosive environments.

In one embodiment of the present invention, the thermoelectric fan 100 comprises a light source, such as a light emitting diode (“LED”), in electrical communication with the thermoelectric module 202. The light source is affixed to the thermoelectric fan 100 in such a manner as to direct light into and thus illuminate the space where the fan is operating. In one embodiment of the present invention, thermoelectric fan 100 comprises a light source in electrical communication with a circuit board assembly 401. In this embodiment, the light source voltage and power specifications are selected to allow for safe operation with the circuit board assembly 401 and thus support operation of the thermoelectric fan 100 within a hazardous atmosphere.

In one embodiment of the present invention, the thermoelectric fan 100 comprises an electrical connection for a rechargeable battery to be in electrical communication with the thermoelectric module 202. In an alternate embodiment, the thermoelectric fan 100 is operated in a hazardous environment and the electrical connection for a rechargeable battery is in electrical communication with the circuit board assembly 401. Suitable connection means include, but not limited to, electrical wires, an integrated power connector, and an electrical receptacle. In another embodiment, a portion of the power generated by the thermoelectric module 202 and electrically transferred to the circuit board assembly 401 is used to provide a voltage to maintain the electrical charge within the battery, or to completely recharge the battery.

The thermoelectric fan of the present invention is secured to a radiant heater, particularly a catalytic heater; the fan may be secured via any suitable means, including but not limited to fastener(s) and bracket(s). The thermoelectric fan 100 may also be placed in close proximity to such a heater rather than being secured thereto.

In one embodiment of the present invention, the thermoelectric fan 100 comprises fasteners 304 and accommodations for fasteners in the thermal plate sub-assembly 102 which provide for the assembly of the thermal plate 301 to the insulation sheet 302 and the insulation shield 303. The heat exchanger disk 204 of the housing sub-assembly 101 comprises a means for affixing it to the thermal plate 301. The thermoelectric fan 100 comprises electrical connections for inserting the one to four diodes, one to four resistors and at least one fuse in an electrical path between the thermoelectric module 202 and motor 203.

Methods for assembling the thermoelectric fan 100 comprise fastening the thermal plate sub-assembly 102 via at least one fastening means 304, the affixing of the thermal plate to the heat exchanger disk via another fastening means. In embodiments in which a circuit board 401 is included, assembling the thermoelectric fan 100 also comprises inserting one to four diodes, one to four resistors and at least one fuse in an electrical path between the thermoelectric module 202 and the motor 203.

The thermoelectric fan 100 is designed to allow for transportation of the housing sub-assembly 101 and the thermal plate sub-assembly 102 unattached. This design reduces the risk of potential shock loads impacting the thermal plate sub-assembly 102 during shipping and transferring high loads into the thermoelectric module 202. The design of the thermoelectric fan of the present invention supports a simple method of installation for affixing the thermal plate sub-assembly 102 to the housing sub-assembly 101 at the location of operation. However, the housing sub-assembly 101 and the thermal plate sub-assembly 102 may be coupled prior to transportation. The present invention also comprises features to allow for simple installation of the thermoelectric fan 100 to the catalytic heater while maintaining proper spacing of the thermal plate sub-assembly 102 from the heater surface.

Methods for installing the thermoelectric fan 100 comprise placing the insulation sheet 302 against the thermal plate 301, in embodiments where the insulation sheet is distinct from the thermal plate, to minimize the heat transfer from the thermal plate to the airflow emanating from the housing 201, and affixing the thermal plate 301 to the heat exchanger disk 204 via a fastening means. The thermoelectric fan is then secured to a radiant heater, particularly a catalytic heater, via a securing means, preferably via brackets 103. Installing the thermoelectric fan also comprises positioning the thermoelectric fan 100 in thermal communication with the heated surface of the heater. The positioning of the thermoelectric fan is made in such a manner as to maximize radiation heat transfer from the heater to the thermal plate 301 and to ensure directed airflow from the thermoelectric fan 100 across the heated surface of the heater. The installation of the thermoelectric fan comprises positioning an extension member in communication with the heated surface of a catalytic heater in such a manner as to create an essential space, in the range of from about 0.125 in. to about 1.0 in., between the thermal plate 301 and the heater surface.

In one embodiment of the present invention, heat is extracted from a radiant heater, preferably a catalytic heater, and converted, at least in part, into an alternative form of energy; the resulting alternative form of energy is utilized to propel an air moving member, such as a fan blade, to power to an illumination device, such as an LED, to charge or recharge charge a battery, or any combination of thereof. The thermoelectric fan of the present invention is utilized to accomplish said extraction and conversion of heat into an alternative form of energy, and said fan is further utilized to communicate the alternative form of energy to achieve the desired useful result.

In one embodiment of the present invention, the thermoelectric fan 100 is operated in a safe manner by limiting the amount of electrical energy supplied by the thermoelectric module 202 to the motor 203. The amount of electrical energy is limited through the use of a circuit board assembly 401, which comprises one to four Zener diodes, one to four resistors and at least one fuse. In a preferred embodiment, the voltage is limited with four 4.7 Volt, 5 Watt Zener diodes positioned electrically in parallel. This preferred embodiment also comprises two 0.25 Ohm, 5 Watt resistors positioned electrically in series, and one 2.0 ampere, 250 Volt fast-acting fuse, electrically in series with the resistors, to limit the current. The circuit board assembly 401 limits the amount of energy which can be transferred to the motor 203 and potentially released in the event of a fault condition. The potential level of energy which can thus be released is of low enough value to prevent the ignition of gases in the environment surrounding the thermoelectric fan 100.

As noted above, the present invention pertains to a thermoelectric fan for radiation-based heaters, particularly catalytic heaters, and methods related thereto. The present invention should not be considered limited to the particular embodiments described above, but rather should be understood to cover all aspects of the invention as fairly set out in the appended claims. Various modifications as well as numerous structures to which the present invention may be applicable will be readily apparent to those skilled in the art to which the present invention is directed upon review of the present specification. The claims are intended to cover such modifications.

We claim:

1. A method for extracting heat from a catalytic radiant heater, converting, at least in part, said heat into an alternative form of energy, and utilizing said energy to achieve a useful result.

2. A method according to claim 1, said useful result being selected from the group consisting of propelling an air moving member, powering an illumination device, charging or re-charging a battery, or combinations thereof.

3. A thermoelectric fan capable of extracting heat from a catalytic radiant heater, converting, at least in part, said heat into an alternative form of energy, and communicating said alternative form of energy to achieve a useful result.

4. A thermoelectric fan according to claim 3, said useful result being selected from the group consisting of propelling an air moving member, powering an illumination device, charging or re-charging a battery, or combinations thereof.

5. A thermoelectric fan, designed for use with a catalytic heater, comprising:
a) a housing sub-assembly comprising a housing comprising at least one thermal heat transfer member, said housing having at least one airflow inlet and at least one airflow outlet; a thermoelectric module in thermal communication with the housing; a motor in electrical communication with the thermoelectric module and coupled to the housing; a heat exchanger disk in thermal communication with the thermoelectric module; an insulating pad in thermal communication with the thermoelectric module, the heat exchanger disk, and the housing; and at least one air moving member coupled to the motor;
b) a thermal plate sub-assembly comprising a thermal plate, said thermal plate having a size and shape capable of blocking the exit airflow from the at least one housing outlet; and, an insulation sheet in thermal communication with the thermal plate, said insulation sheet having a size and shape consistent with the size and shape of said thermal plate and capable of blocking the exit airflow from the at least one housing outlet from contacting the thermal plate; and,
c) an extension member capable of preventing physical contact between the thermal plate and the heated surface of the heater, said extension member integrated into an element of the housing sub-assembly or into an element of the thermal sub-assembly,
wherein, said thermal plate being in thermal communication with said heat exchanger disk.

6. A thermoelectric fan according to claim 5, comprising an insulation shield in communication with the insulation sheet and the heat exchanger disk.

7. A thermoelectric fan according to claim 5, comprising at least one fastening means capable of assembling the thermal plate sub-assembly.

8. A thermoelectric fan according to claim 5, comprising a circuit board assembly.

9. A thermoelectric fan according to claim 8, said circuit board comprising one to four Zener diodes, one to four resistors, and at least one fuse.

10. A thermoelectric fan according to claim 8, comprising an electrical wiring coupled to the circuit board assembly and the thermoelectric module, and an electrical wiring coupled to the circuit board assembly and the motor.

11. A thermoelectric fan according to claim 5, said insulating pad surrounding the outer perimeter of the thermoelectric module.

12. A thermoelectric fan according to claim 5, said thermal plate having a shape in conformity with the geometry of the heated surface.

13. A thermoelectric fan according to claim 5, said thermal plate comprising a thermally conductive material.

14. A thermoelectric fan according to claim 5, said thermal plate having a thickness in the range of from about 0.0625 in. to about 1.0 in.

15. A thermoelectric fan according to claim 6, said insulation sheet having a thickness in the range of from about 0.0625 in. to about 1.0 in.

16. A thermoelectric fan according to claim 6, said insulation sheet comprising a first surface and a second surface, wherein the first surface being in communication with the thermal plate, and the second surface being in communication with the insulation shield.

17. A thermoelectric fan according to claim 5, said fan being secured to a catalytic heater via at least one securing means.

18. A thermoelectric fan according to claim 5, said thermoelectric fan comprising a light source, said light source being in electrical communication with the thermoelectric module.

19. A thermoelectric fan according to claim 5, said thermoelectric fan comprising a means for electrically communicating with a rechargeable battery.

20. A method for assembling the thermoelectric fan of claim 9, comprising inserting the one to four diodes and the one to four resistors in an electrical path between the thermoelectric module and the motor, wherein the one to four diodes and the one to four resistors being capable of limiting the voltage and current from the thermoelectric module to the motor.

21. A method for installing the thermoelectric fan of claim 5, comprising affixing the thermal plate to the heat exchanger disk.

22. A method according to claim 21, said affixing comprising placing the insulation sheet against the thermal plate to minimize the heat transfer from the thermal plate to the airflow emanating from the housing.

23. A method for installing the thermoelectric fan of claim 5, comprising positioning the extension member in communication with the heated surface of a catalytic heater, said positioning creating a space between the thermal plate and the heater surface, said space being in the range of from about 0.25 in. to about 1.0 in.

24. A method according to claim 23, comprising securing the thermoelectric fan to the catalytic heater via at least one securing means.

25. A method of safe operation of the thermoelectric fan of claim 9, comprising limiting the voltage and current through the one to four Zener diodes, the one to four resistors, and the at least one fuse, said voltage being limited to the range of from about 1 Volt to about 10 Volts, and said current being limited to the range of from about 0.5 Amp to about 10 Amps.
